(19) United States
(12) Patent Application Publication
(10) Pub. No.: US 2006/0285298 A1
(43) Pub. Date: Dec. 21, 2006

(54) Heat sink and its fabrication method

(75) Inventor: Yen-Hsun Chou, Taoyuan County (TW)

Correspondence Address: BROWDY AND NEIMARK, P.L.L.C.;624 NINTH STREET, NW, SUITE 300, WASHINGTON, DC, 20001-5303, US

(73) Assignee: YUH-CHENG CHEMICAL LTD., Taipei City (TW)

(21) Appl. No.: 11/156,597

(22) Filed: Jun. 21, 2005

(51) Int. Cl. H05K 7/20

(52) U.S. Cl. 361/710

(57) ABSTRACT

A heat sink is disclosed to include a plurality of plate members arranged in a stack, each plate member having a rectangular body, a mounting hole in the rectangular body near one lateral side, a first sidewall perpendicularly extending from one lateral side of the rectangular body, a second sidewall perpendicularly extending from the other lateral side of the rectangular body, a through hole formed in the first sidewall and connected to the mounting hole, and a hook downwardly extending from the bottom side of the first sidewall. The hook of one plate member is inserted into the mounting hole of another plate member and then deformed to secure the two plate members firmly together.

### BACKGROUND OF THE INVENTION

1. Field of the Invention

The present invention relates to a heat sink for dissipating heat from a heat source and more particularly, to such a heat sink, which has a steady structure and is easy to assemble.

2. Description of the Related Art

A conventional heat sink 1, as shown in FIG. 1, comprises a plurality of metal plate members 2 arranged in a stack. Each metal plate member 2 comprises a plurality of mounting lugs 3 and a plurality of mounting holes 4. Each mounting lug 3 has a base 5 and two arms 6 at two sides of the base 5. During installation, the mounting lugs 3 of one metal plate member 2 are respectively inserted into the mounting holes 4 of another metal plate member 2, and then the arms 6 of the mounting lugs 3 are hammered down, thereby securing the respective mounting lugs 3 to the respective mounting holes 4. This heat sink assembly process requires much time and labor, resulting in a high manufacturing cost.

### SUMMARY OF THE INVENTION

The present invention has been accomplished under the circumstances in view. It is one object of the present invention to provide a heat sink, which has a steady structure and is easy to assemble.

To achieve this and other objects of the present invention, the heat sink comprises a plurality of plate members arranged in a stack. Each plate member comprises a rectangular body, a first sidewall perpendicularly extending from a first side of the rectangular body, and a second sidewall perpendicularly extending from a second side of the rectangular body. The rectangular body has a mounting hole. The first sidewall has a through hole abutted against the rectangular body and connected to the mounting hole, and a hook downwardly extending from a bottom side thereof. The plate members are fastened together by inserting the hook of one plate member inserted into the mounting hole of another plate member and then deforming the hook.

### BRIEF DESCRIPTION OF THE DRAWINGS

FIG. 1 is a perspective view of a part of a heat sink according to the prior art.

FIG. 2 is a side view of a plate member for heat sink according to the present invention.

FIG. 3 is a top view of the plate member shown in FIG. 2.

FIG. 4 is a schematic drawing showing the assembly procedure of a heat sink according to the present invention.

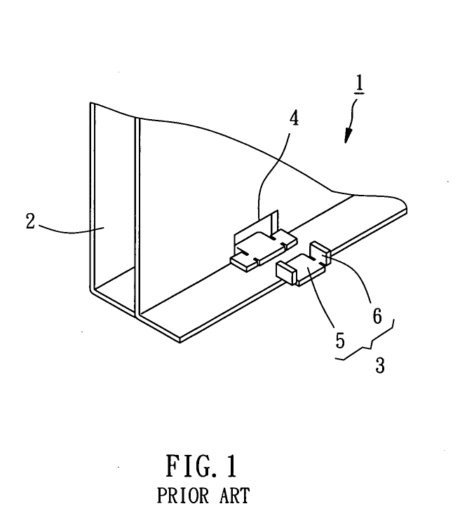

### DETAILED DESCRIPTION OF THE INVENTION

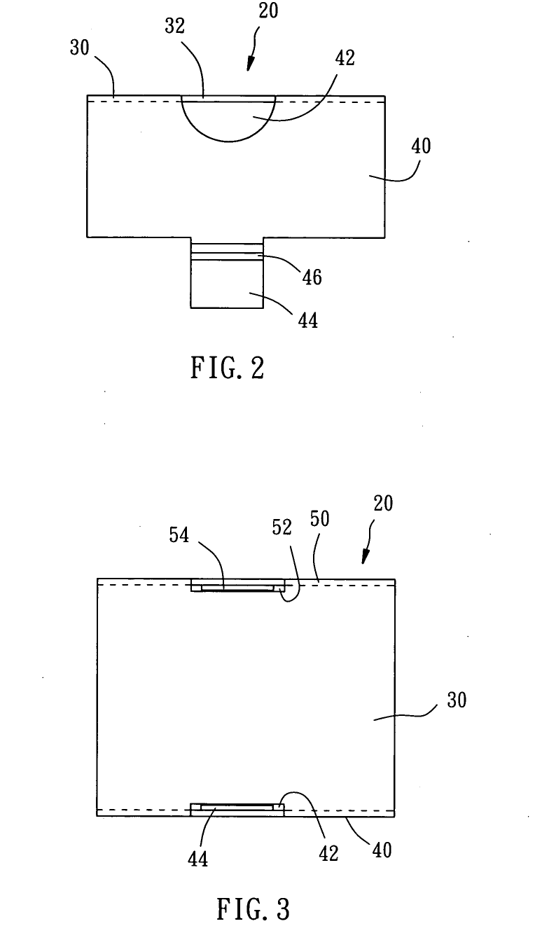

Referring to FIGS. 2-4, a heat sink 10 in accordance with the present invention is shown comprised of a plurality of plate members 20 arranged in a stack. Each plate member 20 has a flat rectangular body 30, and two parallel sidewalls, namely, the first sidewall 40 and the second sidewall 50 respectively perpendicularly extending from two opposite long sides of the rectangular body 30 in same direction.

The flat rectangular body 30 has two mounting holes 32 symmetrically disposed adjacent to sidewalls 40 and 50.

The first sidewall 40 comprises a through hole 42 and a hook 44. The through hole 42 is a semicircular hole abutted against the rectangular body 30 and connected to one mounting hole 32 of the rectangular body 30. The hook 44 extends downwards from the bottom side of the first sidewall 40, having a transversely extending groove 46 near the top.

Similar to the structure of the first sidewall 40, the second sidewall 50 comprises a through hole 52 and a hook 54. The hook 54 extends downwards from the bottom side of the second sidewall 50, having a transversely extending groove 56 near the top.

Further, the width of the hook 44 or 54 is smaller than the width of the mounting holes 32.

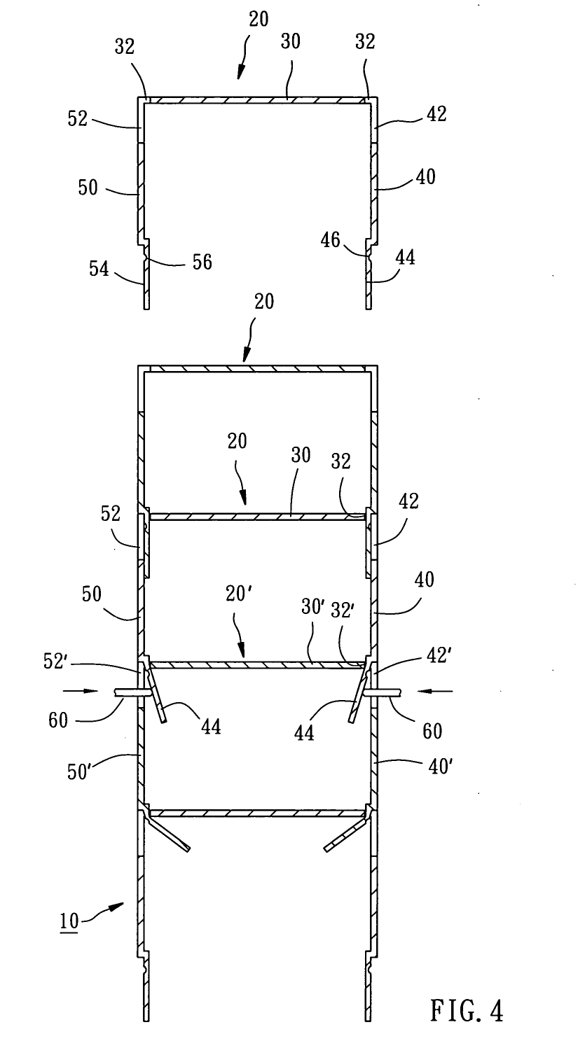

Referring to FIG. 4 again, when assembling the plate members 20 to form the desired heat sink 10, the two hooks 44 and 54 of a first plate member 20 are respectively inserted into the mounting holes 32′ of a second plate member 20′, and then two rods 60 are respectively inserted through the through holes 42′ and 52′ of the second plate member 20′ and pressed against the hooks 44 and 54 of the first plate member 20 to deform the hooks 44 and 54. Because of the presence of the transversely extending grooves 46 and 56, the hooks 44 and 54 can easily be deformed inwards to secure the second plate member 20′ to the first plate member 20 firmly. By mans of repeating the aforesaid procedure, all the plate members 20 are fastened together to form the desired heat sink 10.

Further, according to the aforesaid first embodiment of the present invention, the first sidewall and the second sidewall are respectively perpendicularly extending from the two opposite long sides of the rectangular body in same direction. Alternatively, the first and second sidewalls can be respectively perpendicularly extending from two adjacent sides of the rectangular body; the number and shape of the hooks, mounting holes or through holes be variously embodied.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A heat sink comprising a plurality of plate members arranged in a stack, said plate members each comprising a rectangular body, a first sidewall perpendicularly extending from a first side of said rectangular body, and a second sidewall perpendicularly extending from a second side of said rectangular body, said rectangular body having a mounting hole, said first sidewall having a through hole and a hook obliquely downwardly extending from a bottom side of said first sidewall, the hook of one of said plate members being engaged into the mounting hole of another one of said plate members.

2. The heat sink as claimed in claim 1, wherein said hook has a first width; said mounting hole has a second width greater than said first width.

3. The heat sink as claimed in claim 1, wherein said hook has a transversely extending groove.

4. The heat sink as claimed in claim 1, wherein said through hole is a semicircular hole.

5. The heat sink as claimed in claim 1, wherein said mounting hole is abutted against said first sidewall and connected to said through hole.

6. A heat sink fabrication method comprising the steps of:
(a) preparing a plurality of plate members, said plate members each comprising a rectangular body, a first sidewall perpendicularly extending from a first side of said rectangular body, and a second sidewall perpendicularly extending from a second side of said rectangular body, said rectangular body having a mounting hole, said first sidewall having a through hole and a hook downwardly extending from a bottom side thereof;
(b) inserting the hook of a first one of said plate members into the mounting hole of a second one of said plate members; and
(c) inserting a rod into the through hole of said second one of said plate members to press the hook of said first one of said plate members and to further deform the hook of said first one of said plate members, thereby securing the two plate members firmly together.

7. The heat sink fabrication method as claimed in claim 6, wherein said hook has a transversely extending groove.

8. The heat sink fabrication method as claimed in claim 6, wherein said mounting hole is abutted against said first sidewall and connected to said through hole.
